(19) United States
(12) Patent Application Publication
(10) Pub. No.: US 2014/0057418 A1
(43) Pub. Date: Feb. 27, 2014

(54) METHOD FOR MANUFACTURING A SEMICONDUCTOR DEVICE

(71) Applicants: Xiaolong Ma, Beijing (CN); Huaxiang Yin, Beijing (CN); Zuozhen Fu, Beijing (CN)

(72) Inventors: Xiaolong Ma, Beijing (CN); Huaxiang Yin, Beijing (CN); Zuozhen Fu, Beijing (CN)

(21) Appl. No.: 13/812,502

(22) PCT Filed: Oct. 12, 2012
(86) PCT No.: PCT/CN2012/001375

§ 371 Date: Jan. 26, 2013

(30) Foreign Application Priority Data
Aug. 16, 2012 (CN) 201210293349.X

(51) Int. Cl. H01L 21/02; H01L 29/12

(52) U.S. Cl. CPC H01L 21/0257; H01L 29/12; H01L 21/02521; H01L 21/02617
USPC 438/479

(57) ABSTRACT

The present invention discloses a method for manufacturing a high mobility material layer, comprising: forming a plurality of precursors in/on a substrate; and performing a pulse laser processing such that the plurality of precursors react with each other to produce a high mobility material layer. Furthermore, the present invention also provides a method for manufacturing a semiconductor device, comprising: forming a buffer layer on an insulating substrate; forming a first high mobility material layer on the buffer layer using the method for manufacturing the high mobility material layer; forming a second high mobility material layer on the first high mobility material layer using the method for manufacturing the high mobility material layer; and forming trench isolations and defining active regions in the first and second high mobility material layers.

### CROSS REFERENCE

This application is a National Phase application of, and claims priority to, PCT Application No. PCT/CN2012/001375, filed on Oct. 12, 2012, entitled ‘METHOD FOR MANUFACTURING A SEMICONDUCTOR DEVICE’, which claimed priority to Chinese Application No. CN 201210293349.X, filed on Aug. 16, 2012. Both the PCT Application and Chinese Application are incorporated herein by reference in their entireties.

### FIELD OF THE INVENTION

The present invention relates to the field of manufacture of a semiconductor integrated circuit, in particular, to a method for manufacturing a semiconductor structure having a high mobility channel region on an insulator.

### BACKGROUND OF THE INVENTION

With the on-going development of the integrated circuit technology, particularly the continuous reduction of the device size in scale, various key parameters of the device such as the threshold voltage are also reduced accordingly, the advantages of reduction in the power consumption and increase in the integration can promote the enhancement of the overall performance of the device. However, at the same time, the device drive capability is limited by the traditional technology of silicon material, the carrier mobility is low, thus a problem of a relatively low device drive capability is confronted with. Accordingly, the high mobility channel device finds a very important application prospect in the future.

For existing high mobility channel devices, generally Si₁₋ₓGeₓ or Si₁₋ₓCₓ is adopted as a stressed source/drain region for applying a stress to the Si channel region, or these materials are directly adopted as the substrate and the channel region. The hole mobility may be further enhanced by introducing a compressive strain into Si₁₋ₓGeₓ, and correspondingly the electron mobility may be further enhanced by introducing a tensile strain into Si₁₋ₓCₓ. However, the lattice constants of the two materials are not sufficiently different from that of Si, they can only provide a limited strain, thus can hardly be applied to the device requiring a higher driving capability.

One alternative material is GeSn alloy, the thin film thereof has a high carrier mobility, and the band structure of the alloy can be adjusted by adjusting the concentration of Sn, thus the material is widely applied to advanced CMOS devices and optoelectronic devices.

However, it needs molecular-beam epitaxy or CVD to form the traditional GeSn alloy, which is still not mature or not compatible with CMOS currently. Besides, since Sn has a very low equilibrium solid solubility in Ge, it is difficult to obtain the Ge₁₋ₓSnₓ with the concentration of Sn higher than 1% by conventional processes.

In addition, other high mobility materials such as GaAs and InSb also have the same problem and can hardly be compatible with the Si-based CMOS process.

### SUMMARY OF THE INVENTION

Accordingly, the present invention aims to provide a method for manufacturing a high mobility material layer on a substrate to be used as a channel region, thereby to overcome the defects in traditional technology and enhance the carrier mobility in the device channel region effectively.

The object of the present invention is realized by providing a method for manufacturing a high mobility material layer, comprising: forming a plurality of precursors in/on a substrate; and performing a pulse laser processing such that the plurality of precursors react with each other to produce a high mobility material layer.

Wherein the step of forming a plurality of precursors further comprises implanting a dopant to the substrate to form precursors in the substrate.

Wherein the implantation energy is about 10 KeV-300 KeV, and the implantation dose is about 1E15-1E17/cm².

Wherein the implantation dose and energy of one of the plurality of precursors are adjusted to control the composition of the high mobility material layer.

Wherein the step of forming a plurality of precursors further comprises depositing precursors on the substrate.

Wherein the pulse number, the energy density and the pulse time of the pulse laser processing and the thickness of one of the plurality of precursors are adjusted to control the thickness of the high mobility material layer.

Wherein after forming the plurality of precursors, the method further comprises forming a protective layer on the precursors.

Wherein the process of forming the protective layer comprises low temperature deposition, spin coating, screen printing and spraying.

Wherein the substrate comprises Si, SOI, Ge, GeOI, SiGe, InP, InGaAs, GaAs, GaN and InSb.

Wherein the substrate has a lattice constant between about 5.4-6.4 Å.

Wherein the substrate is made of a monocrystalline material, and the crystal orientation comprises (100), (110) or (111).

Wherein the precursor comprises Ge, Sn, In, Ga, Si, As, P, N and Sb.

Wherein the high mobility material layer comprises GeSn, SiGeSn, InGeSn, GaGeSn and InGaAs.

Furthermore, the present invention also provides a method for manufacturing a semiconductor device using the above mentioned method for manufacturing a high mobility material layer, comprising: forming a buffer layer on an insulating substrate; forming a first high mobility material layer on the buffer layer using the method for manufacturing a high mobility material layer; forming a second high mobility material layer on the first high mobility material layer using the method for manufacturing a high mobility material layer; and forming trench isolations and defining active regions in the first and second high mobility material layers.

Wherein the first high mobility material layer and/or the second high mobility material layer comprise GeSn.

Wherein the step of forming a buffer layer on an insulating substrate further comprises forming an insulating layer on the substrate; forming insulating layer openings in the insulating layer to expose the substrate; and performing selectively epitaxial growth of a buffer layer in the insulating layer openings.

Wherein the insulating layer is formed by thermal oxidation.

Wherein the buffer layer comprises SiGe and the substrate comprises Si.

Wherein the step of forming the first high mobility material layer further comprises: forming a first material layer and a second material layer on the buffer layer sequentially; performing a first laser processing, wherein a laser pulse is used to irradiate the first material layer and the second material layer such that the first material layer and the second material layer react to produce a first high mobility material layer.

Wherein the step of forming the second high mobility material layer further comprises: forming a third material layer and a fourth material layer on the first high mobility material layer sequentially; performing a second laser processing, wherein a laser pulse is used to irradiate the third material layer and the fourth material layer such that the third material layer and the fourth material layer react to produce a second high mobility material layer.

Wherein the first material layer and/or the third material layer comprise Ge and the second material layer and/or the fourth material layer comprise Sn.

Wherein the step of forming trench isolations and defining active regions further comprises: forming a photoresist pattern having photoresist openings on the second high mobility material layer, wherein the photoresist openings correspond to the buffer layer; etching the second high mobility material layer, the first high mobility material layer, and the buffer layer sequentially to expose the substrate and form trenches; depositing insulating materials in the trenches to form trench isolations, wherein the second high mobility material layer and the first high mobility material layer enclosed by the trench isolations form active regions.

In accordance with the method for manufacturing a semiconductor device of the present invention, multiple layers of high mobility materials to be used as the device channel region are formed on the insulating substrate by many times through adjustment of the pulse number and the energy density of the laser processing, thus the device carrier mobility is effectively enhanced and the device drive capability is further improved.

### BRIEF DESCRIPTION OF THE DRAWINGS

The technical solution of the present invention will be described in detail with reference to the drawings below.

FIGS. 1-12 are diagrammatic cross-sections corresponding to the steps of the method for manufacturing a semiconductor device in accordance with the embodiments of the present invention;

FIG. 13 is a flow chart for the method for manufacturing a semiconductor device in accordance with the embodiments of the present invention; and

FIG. 14 is a flow chart for the method for manufacturing a high mobility material layer in accordance with the embodiments of the present invention.

### DETAILED DESCRIPTION OF THE EMBODIMENTS

The features and the technical effects of the technical solution of the present application will be described in detail in combination with the illustrative embodiments with reference to the drawings. It should be pointed out that like reference signs indicate like structures, the terms such as “first”, “second”, “above”, “below”, “thickness” and “thin” used in the present invention may be used to describe various device structures. Except for specific explanations, these descriptions do not imply the spatial, sequential or hierarchical relationships of the structures of the described device.

First, referring to FIG. 14, it illustrates the flow chart for the method for manufacturing a high mobility material layer.

A substrate is provided. The substrate may either be bulk Si, SOI, bulk Ge, GeOI, SiGe and GeSb, or be other III-V group or II-VI group compound semiconductor substrate such as GaAs, GaN, InP, InSb and InGaAs. In order to be compatible with the existing CMOS technology so as to be applied to manufacturing of large-scale digital integrated circuit, the substrate 1 is preferably made of bulk Si, i.e., silicon wafer. Preferably, the substrate has a lattice constant between about 5.4-6.4 Å. And preferably, the substrate is made of a monocrystalline material, and the crystal orientation is (100), (110) or (111).

Precursors are formed in/on the substrate.

In an embodiment of the present invention, precursors may be formed in the substrate. For example, ion implantation is performed, by which a high dose of Ge and Sn are implanted to the substrate to form GeSn. Furthermore, a plurality of precursors may be formed as for other materials such as InGeSn and GaGeSn. The implantation energy may be, e.g., about 10 KeV-300 KeV, and the implantation dose may be, e.g., about 1E15-1E17/cm². While implanting the precursors, these implanted ions cause amorphization of an area with certain thickness from the substrate surface, so as to be advantageous for diffusion of the precursors when the laser irradiation processing is performed later. The amorphized region has a distance (thickness) of about, e.g., 1-100 nm from the upper surface of the substrate.

In another embodiment of the present invention, two precursors may be formed in the substrate. For example, first, a Ge layer is deposited on the substrate surface by a process of PECVD, HDPCVD, MBE and ALD, and the thickness thereof may be about, e.g., 1-50 nm. Then, a metal Sn layer is deposited on the Ge layer by a process of sputtering, MOCVD and MBE, and the thickness thereof may be about, e.g., 5-40 nm.

Preferably, a protective layer is formed on the precursors. For example, a low-temperature protective layer, e.g., low temperature silicon oxide (LTO), is formed by using a process such as PECVD and LPCVD and decreasing the deposition temperature, that is, depositing a protective layer at a low temperature. The deposition is performed at a temperature, e.g., lower than 400° C. to avoid that Ge and Sn react in advance. Or a protective layer may be formed by a process such as spin coating, screen printing and spraying using glass materials such as PSG and BPSG or even resin materials such as photoresist for avoiding damage to materials in the event of the subsequent excessive laser processing. Of course, if the laser processing parameters can be well adjusted, the protective layer may also be omitted.

Then, a laser processing is performed, that is, the two precursors are irradiated by a laser pulse such that the temperature rises quickly at the surfaces of the two precursors, which melt and react with each other, crystallize in the same crystal orientation as that of the substrate during the cooling process, and finally form an alloy as a high mobility layer. Wherein the so-called high mobility means that the hole or electron mobility in the material layer is higher than that in the channel region of silicon material substrate in the traditional CMOS technology, and preferably, the high mobility is 1.5 times or more than the mobility in Si. In an embodiment of the present invention, the high mobility layer is made of GeSn. The pulse number of the laser processing is m1 (e.g., an integer of 1-100), the energy density thereof is f1 (e.g., about 100 mJ/cm²-1 J/cm²), the laser wavelength is about 157 nm-10.6 μm and the pulse time width is t1 (e.g., about 1 ns-10 μs). The thickness of the alloy layer may be controlled by adjusting the above laser pulse parameters.

Besides, in the process of performing implantation to form precursors, the composition of the alloy (e.g., GeSn), such as the proportion, may be correspondingly adjusted by adjusting the dose and energy of one of the implanted precursors. Specifically, the high mobility layer may be Ge1-xSnx, wherein preferably 0<x<0.3, and the thickness thereof may be, e.g., of about 5 nm-200 nm.

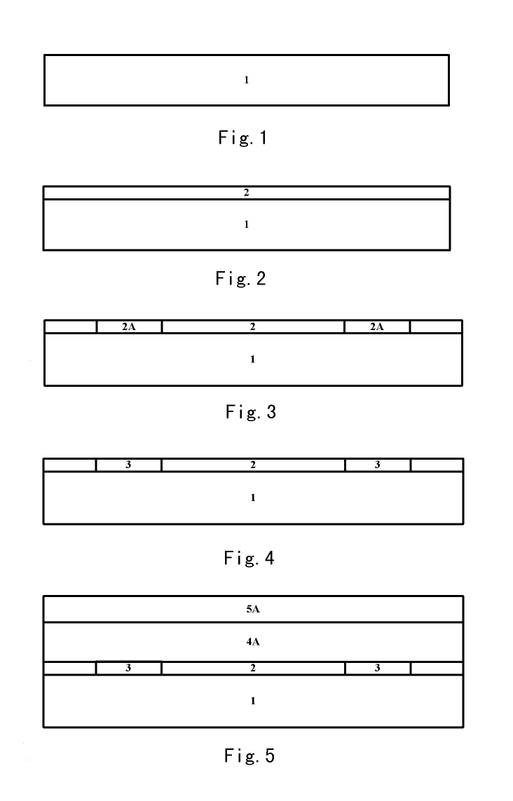

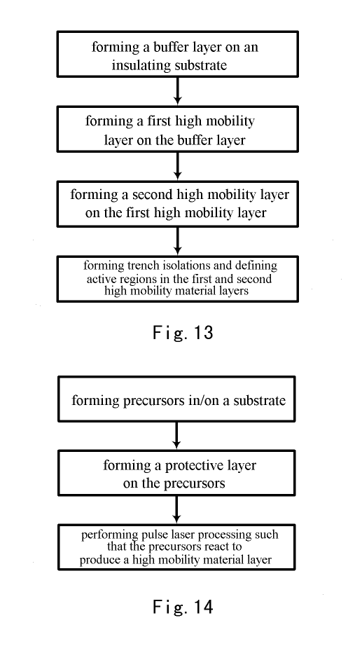

The method for manufacturing a high mobility material of the present invention is disclosed above with reference to the flow chart FIG. 14, and hereinafter the specific steps of the method for manufacturing a semiconductor device using the method for manufacturing the high mobility material will be described in detail with reference to the flow chart FIG. 13 as well as FIGS. 1-12.

Referring to FIG. 13 as well as FIGS. 1-4, a buffer layer is formed on an insulating substrate.

As shown in FIG. 1, a substrate 1 is provided, the substrate may either be bulk Si, SOI, bulk Ge, GeOI, SiGe and GeSb, or be other III-V group or II-VI group compound semiconductor substrate such as GaAs, GaN, InP and InSb. Furthermore, the substrate may also be a transparent substrate of glass, plastic, and resin etc. In order to be compatible with the existing CMOS technology so as to be applied to manufacturing of large-scale digital integrated circuit, the substrate 1 is preferably made of bulk Si, i.e., silicon wafer. Preferably, the substrate has a lattice constant between about 5.4-6.4 Å. And preferably, the substrate is made of a monocrystalline material, and the crystal orientation is (100), (110) or (111).

As shown in FIG. 2, an insulating layer 2 is formed on the substrate 1. The insulating layer 2 made of silicon oxide is formed by a process such as LPCVD, PECVD, HDPCVD and thermal oxidation for insulating and isolating the substrate to reduce the leakage current and/or the parasite effect of the substrate. Preferably, the silicon oxide layer 2 is formed by thermal oxidation to improve the quality of the insulating layer 2 and reduce defects. The insulating layer 2 may have a thickness, which is set depending on the requirement of the isolation and insulation performance of the device, e.g., about 10-500 nm.

As shown in FIG. 3, photolithography/etching are performed on the insulating layer 2 to expose the substrate 1, thereby forming a plurality of insulating layer openings 2A in the insulating layer 2. The plurality of insulating layer openings 2A are shown as two openings in FIG. 3 (one at left, the other at right), each of which, however, is an “annular window” in the periphery of an area corresponding to the active region of the later formed device in the top view (not shown), in other words, an active region will be formed and defined in an area at the inner side of the insulating layer openings 2A, and the area at the outer side of the insulating layer openings 2A corresponds to the isolation region of the device. The insulating layer opening 2A may have a width (that is, the distance between the inner and outer edges of the annular window) which is set depending on the requirement of the device size, specifically depending on the width of the active region and the requirement of adjustment of the lattice transition, e.g., about 50-1000 nm.

As shown in FIG. 4, a buffer layer 3 is formed within the plurality of insulating layer openings 2A in the insulating layer 2 by selectively epitaxial growth. Since material Si of the substrate 1 is different from material silicon oxide of the insulating layer 2, the buffer layer 3 formed by an epitaxial process such as MBE and ALD is preferably grown in the insulating layer openings 2A only, that is, the buffer layer 3 is formed by selectively epitaxial growth. The material of the buffer layer 3 will has a lattice constant between the lattice constant of the substrate 1 and that of the high mobility material to be formed later. For example, when the substrate 1 is Si and the high mobility material is GeSn, the buffer layer 3 may be SiGe, so as to control the growth orientation of GeSn and decrease the lattice mismatch between the substrate 1 and the later formed high mobility material channel layer. SiGe may be specifically set depending on the requirement of adjusting the lattice mismatch, e.g., Si1-zGez, wherein the atomic percent of Ge may be greater than or equal to 50%, that is, 0.5<z<1. Preferably, after selectively epitaxial growth of the buffer layer 3, a planarization process such as CMP is performed to expose the insulating layer 2 such that the buffer layer 3 has the same thickness as the insulating layer openings 2A.

Next, referring to FIG. 13 and FIGS. 5-7, the method as shown in FIG. 14 is used to form a first high mobility material layer on the buffer layer, to be used as a part of the later formed channel region, thus it may also be called as the first channel layer. Wherein the so-called high mobility means that the hole or electron mobility in the material layer is higher than that in the channel region of silicon material substrate in the traditional CMOS technology, and preferably, the high mobility is 1.5 times or more than the mobility in Si.

As shown in FIG. 5, a first material layer 4A and a second material layer 5A are deposited sequentially on the insulating layer 2 and the buffer layer 3. The deposition may be performed by a process such as PECVD, MBE, ALD and sputtering. For the first high mobility material layer that is made of GeSn, the first material layer 4A is made of amorphous Ge and has a thickness t1 and the second material layer 5A is made of metal Sn and has a thickness t2, wherein t1 and t2 may be arbitrarily set depending on the alloy proportion. Preferably, a low-temperature protective layer, e.g., low temperature silicon oxide (LTO), is formed on the second material layer 5A by using a process such as PECVD and LPCVD and decreasing the deposition temperature. The deposition is performed at a temperature, e.g., lower than 400° C. to avoid that Ge and Sn react in advance. Or a protective layer may be formed by spin coating glass materials such as PSG and BPSG or even resin materials such as photoresist for avoiding damage to materials in the event of the subsequent excessive laser processing. Of course, if the laser processing parameters can be well adjusted, the protective layer may also be omitted.

As shown in FIGS. 6 and 7, a first laser processing is performed, that is, a laser pulse is used to irradiate the first material layer 4A and the second material layer 5A such that the temperature rises quickly at the surface of the samples, which melt and react, crystallize in the same crystal orientation as that of the substrate during the cooling process, and finally form a high mobility layer 6A as shown in FIG. 7. The pulse number of the laser processing is m1 (e.g., an integer of 1-100), the energy density thereof is f1 (e.g., about 100 mJ/cm²-1 J/cm²), the laser wavelength is about 157 nm-10.6 μm and the pulse time width is t1 (e.g., about 1 ns-10 μs). If the layer 4A is made of Ge and the layer 5A is made of Sn, then the first high mobility layer 6A produced by reaction may be Ge1-xSnx, wherein preferably 0<x<0.1, and the first high mobility layer 6A may have a thickness of, e.g., about 5 nm-200 nm. In this case, although the concentration of Sn in Ge₁₋ₓSnₓ may be controlled by adjusting the number and energy density of the laser pulse, the concentration of Sn will normally be not higher than 0.1 even if it is raised, due to crystal lattice and orientation of SiGe of the base buffer layer 3, which is not enough for a device requiring a much higher mobility channel region, thus a subsequent further processing of the present invention is needed.

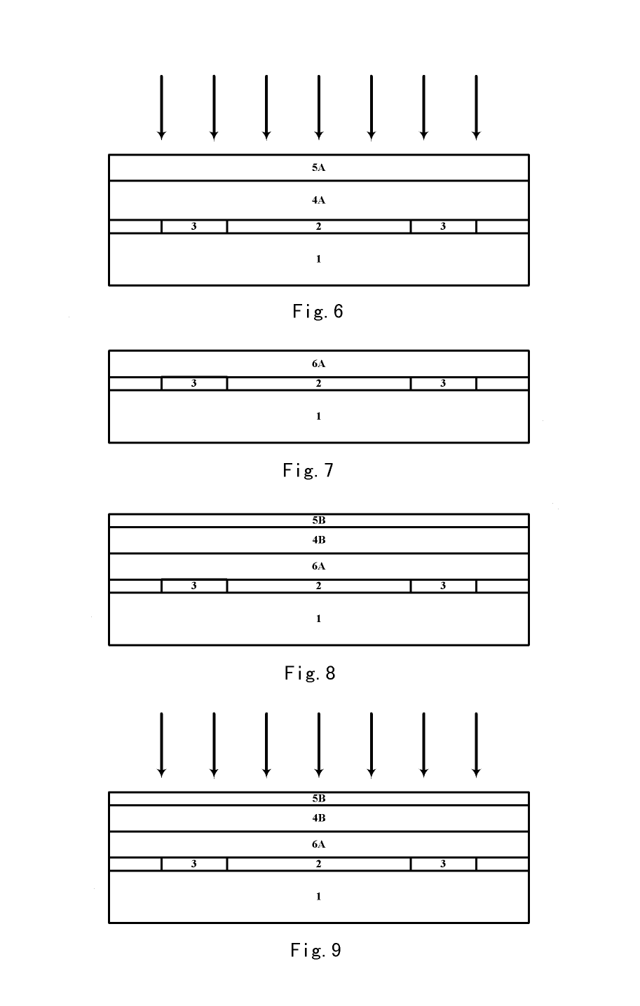

Then, referring to FIG. 13 and FIGS. 8-10, a second high mobility material layer is formed on the first high mobility material layer to be used as a second part of the later formed channel region, thus it may also be called as the second channel layer. Wherein the second high mobility material layer has a carrier mobility larger than that of the first high mobility material layer.

Similar to FIGS. 5-7, a second high mobility material layer may be formed by using the same method.

Specifically, as shown in FIG. 8, a third material layer 4B and a fourth material layer 5B are deposited sequentially on the first high mobility material layer 6A. The deposition may be performed by a process such as PECVD, MBE, ALD and sputtering. Wherein if the second high mobility material layer is made of the same material as the first high mobility material layer, then the third material layer 4B is made of the same material as the first material layer 4A, and the fourth material layer 5B is made of the same material as the second material layer 5A. For example, the third material layer 4B is made of amorphous Ge and has a thickness t3, and the second material layer 5A is made of metal Sn and has a thickness t4, wherein t3 and t4 may be arbitrarily set depending on the alloy proportion. Furthermore, the second high mobility material layer may also be made of a material different from that of the first high mobility material layer, e.g., SiGeSn alloy, GaGeSn alloy, InGeSn, and GeSnAs alloy, thus the third material layer 4B may be made of e.g., Si, Ge, In and Ga, and the fourth material layer 5B may be made of e.g., Sn and As. Also preferably, a protective layer similar to the above may also be formed on the fourth material layer 5B.

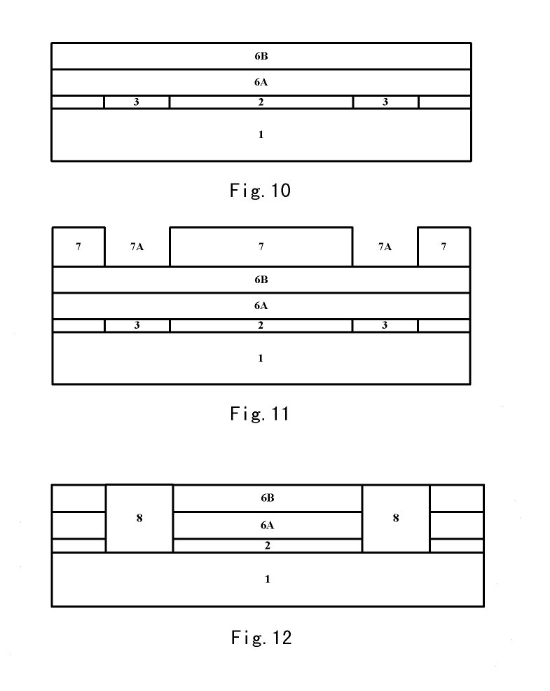

As shown in FIGS. 9 and 10, a second laser processing is performed, that is, a laser pulse is used to irradiate the third material layer 4B and the fourth material layer 5B such that the temperature rises quickly at the surface of the samples, which melt and react, crystallize in the same crystal orientation as that of the first high mobility material layer during the cooling process, and finally form a second high mobility layer 6B as shown in FIG. 10. The pulse number of the second laser processing is m2 (e.g., 10-200), which is different from the above m1, the energy density thereof is f2 (e.g., about 400 mJ/cm²-2 J/cm²) which is different from the above f1. If the layer 4A is made of Ge and the layer 5A is made of Sn, then the second high mobility layer 6A produced by reaction may be Ge1-ySny, wherein y shall be greater than the x, preferably 0.1<y<0.3. The second high mobility layer 6B may have a thickness of, e.g., about 5 nm-200 nm. In this case, since the first high mobility layer 6A functions as transition and buffer and the laser pulse processing parameters are changed, the second high mobility layer 6B has a more reasonable lattice arrangement, the concentration of Sn therein may be significantly increased, thus the device drive capability is effectively enhanced.

In addition, although the present invention only illustrates that two high mobility material layers are laminated to be used as the channel region in the embodiment, a stacked structure of multiple layers such as three layers, four layers or even more layers of GeSn, or a mixed stacked structure of no less than three layers comprising different high mobility materials such as SiGe, GaAs, GeSn and InSb may be set depending on the requirement, so long as the requirement that the carrier mobility in the layers is gradually increased from the bottom to the top can be met.

Thereafter, referring to FIG. 13 and FIGS. 11 and 12, trench isolations are formed and active regions are defined in the first and second high mobility material layers.

As shown in FIG. 11, a photoresist 7 is coated, and exposed/developed on the second high mobility material layer 6B to form a photoresist pattern having a plurality of photoresist openings 7A, which expose the second high mobility material layer 6B. Wherein, the photoresist openings 7A correspond to the locations of the insulating layer openings 2A, that is, annular windows are formed. The photoresist openings 7A may have a width equal to that of the insulating layer openings 2A/buffer layer 3 as shown in FIG. 11, and may preferably have a width greater than that of the insulating layer openings 2A.

As shown in FIG. 12, the second high mobility material layer 6B, the first high mobility material 6A, and the buffer layer 3 are sequentially etched by an anisotropic dry etching such as plasma etching and reactive ion etching, to expose the substrate 1 and form trenches. Then, trench isolations 8 are formed by depositing insulating materials such as silicon oxide, silicon oxynitride, BPSG and PSG in the trenches by a process such as LPCVD, PECVD, HDPCVD and spin coating. The trench isolations 8 are conformal to the photoresist openings 7A and the insulating layer openings 2A, thus have annular window structures, the second high mobility material layer 6B and the first high mobility material layer 6A enclosed at the inner side therein constitute the source/drain regions and channel regions of the device, that is, the trench isolations 8 define the active regions.

Later, the device is finished. For example, as for a MOSFET, a CMOS compatible technology may be used to form gate stacks on the active regions inside the trench isolations 8, perform doping implantation in the active regions to form source/drain regions, form a source/drain contact layer on the source/drain regions, form an interlayer dielectric layer on the entire device, etch the interlayer dielectric layer to form source/drain contact holes, and deposit metal to form source/drain contact plugs etc.

In accordance with the method for manufacturing a semiconductor device of the present invention, multiple layers of high mobility materials to be used as the device channel region are formed on the insulating substrate by many times through adjustment of the pulse number and the energy density of the laser processing, thus the device carrier mobility is effectively enhanced and the device drive capability is further improved.

Although the present invention has been described with reference to one or more illustrative embodiments, it may be appreciated by those skilled in the art that various appropriate modifications and equivalents can be made to the method for forming the device structure without departing from the scope of the present invention. Besides, many modifications adaptable to specific situations or materials can be made under the disclosed teaching without departing from the scope of the present invention. Therefore, it is not intended to limit the present invention to the specific embodiments which are disclosed as the preferred embodiments for implementing the present invention, the disclosed device structure and the manufacturing method thereof will include all the embodiments that come within the scope of the present invention.

1. A method for manufacturing a high mobility material layer, comprising:
forming a plurality of precursors in/on a substrate; and
performing a pulse laser processing such that the plurality of precursors react with each other to produce a high mobility material layer.

2. The method of claim 1, wherein the step of forming a plurality of precursors further comprises implanting a dopant to the substrate to form precursors in the substrate.

3. The method of claim 2, wherein the implantation energy is about 10 KeV-300 KeV, and the implantation dose is about 1E15-1E17/cm².

4. The method of claim 2, wherein the implantation dose and energy of one of the plurality of precursors are adjusted to control the composition of the high mobility material layer.

5. The method of claim 1, wherein the step of forming a plurality of precursors further comprises depositing a plurality of precursors on the substrate.

6. The method of claim 5, wherein the pulse number, the energy density and the pulse time of the pulse laser processing and the thickness of one of the plurality of precursors are adjusted to control the thickness of the high mobility material layer.

7. The method of claim 1, wherein after forming the plurality of precursors, the method further comprises forming a protective layer on the precursors.

8. The method of claim 7, wherein the process of forming the protective layer comprises low temperature deposition, spin coating, screen printing and spraying.

9. The method of claim 1, wherein the substrate comprises Si, SOI, Ge, GeOI, SiGe, InP, InGaAs, GaAs, GaN and InSb; the precursor comprises Ge, Sn, In, Ga, Si, As, P, N and Sb; and the high mobility material layer comprises GeSn, SiGeSn, InGeSn, GaGeSn and InGaAs.

10. A method for manufacturing a semiconductor device, comprising:
forming a buffer layer on an insulating substrate;
forming a first high mobility material layer on the buffer layer using the method of any one of claims 1;
forming a second high mobility material layer on the first high mobility material layer using the method of any one of claims 1; and
forming trench isolations and defining active regions in the first and second high mobility material layers.

11. The method of claim 10, wherein the first high mobility material layer and/or the second high mobility material layer comprise GeSn.

12. The method of claim 10, wherein the step of forming a buffer layer on an insulating substrate further comprises:
forming an insulating layer on the substrate;
forming insulating layer openings in the insulating layer to expose the substrate; and
performing selectively epitaxial growth of a buffer layer in the insulating layer openings.

13. The method of claim 12, wherein the insulating layer is formed by thermal oxidation.

14. The method of claim 10, wherein the buffer layer comprises SiGe and the substrate comprises Si.

15. The method of claim 10, wherein the step of forming the first high mobility material layer further comprises:
forming a first material layer and a second material layer on the buffer layer sequentially; and
performing a first laser processing, wherein a laser pulse is used to irradiate the first material layer and the second material layer such that the first material layer and the second material layer react to produce a first high mobility material layer.

16. The method of claim 10, wherein the step of forming the second high mobility material layer further comprises:
forming a third material layer and a fourth material layer on the first high mobility material layer sequentially; and
performing a second laser processing, wherein a laser pulse is used to irradiate the third material layer and the fourth material layer such that the third material layer and the fourth material layer react to produce a second high mobility material layer.

17. The method of claim 15, wherein the first material layer comprises Ge and the second material layer comprises Sn.

18. The method of claim 10, wherein the step of forming trench isolations and defining active regions further comprises:
forming a photoresist pattern having photoresist openings on the second high mobility material layer, wherein the photoresist openings correspond to the buffer layer;
etching the second high mobility material layer, the first high mobility material layer, and the buffer layer sequentially to expose the substrate and form trenches; and
depositing insulating materials in the trenches to form trench isolations, wherein the second high mobility material layer and the first high mobility material layer enclosed by the trench isolations form active regions.

19. The method of claim 16, wherein the third material layer comprises Ge and the fourth material layer comprises Sn.
